(19) United States
(12) Patent Application Publication
(10) Pub. No.: US 2015/0305186 A1
(43) Pub. Date: Oct. 22, 2015

(54) Electronic Device Cover Assembly

(71) Applicant: Christopher Murray, Hollywood, FL (US)

(72) Inventor: Christopher Murray, Hollywood, FL (US)

(21) Appl. No.: 14/684,834

(22) Filed: Apr. 13, 2015

Related U.S. Application Data
(60) Provisional application No. 61/980,249, filed on Apr. 16, 2014.

(51) Int. Cl. H05K 5/03; H05K 5/02

(52) U.S. Cl. CPC H05K 5/03; H05K 5/0217

(57) ABSTRACT

An electronic device cover assembly is provided. The electronic device cover assembly is configured to provide a convenient apparatus that allows a user to store his personal items in the same location as his electronic device. The assembly includes a cover configured to receive an electronic device therein. The cover includes grooves along an outer edge of a rear portion of the cover and at least one latching fastener configured to removably attach one of a plurality of interchangeable accessory portions. The interchangeable accessory portions include a first accessory portion having a housing and at least one sliding mechanism configured to support a user's keys. A second accessory portion includes a housing divided into a plurality of compartments configured to support a user's medicinal pills. A third accessory portion includes a battery pack configured to provide electrical power to the electronic device supported within the cover.

### CROSS REFERENCE TO RELATED APPLICATION

This application claims the benefit of U.S. Provisional Application No. 61/980,249 filed on Apr. 16, 2014. The above identified patent application is herein incorporated by reference in its entirety to provide continuity of disclosure.

### FIELD OF THE INVENTION

The present invention relates to electronic device accessories. Specifically, the present invention relates to an electronic device cover assembly having a plurality of interchangeable accessory portions configured to support other personal items with an electronic device supported within a cover.

### BACKGROUND OF THE INVENTION

Personal items such as wallets, phones, and keys, are important things that need to be accounted for at all times. However, more often than not, these items are placed throughout a house, and the entire house needs to be searched in order to track down these personal items. Sometimes, electronic devices are kept in the bedroom or in other rooms, while wallets and keys are separately stored in different rooms. It is often time consuming and burdensome to locate these personal items. In addition, in urgent times, it can also be emotional draining and frustrating to spend precious time searching for personal items.

Furthermore, a person that is a frequent business traveler needs to be constantly aware of his personal items. For example, while staying in a hotel room, a user may have to create a mental checklist of all his personal items before leaving. Some items may be lurking in a corner, placed on a bedside table, or on the bathroom counter. In another example, a passenger under duress travelling on a plane or a train may be under pressure to leave quickly. However, after traveling for an extended period of time, these personal items need to be quickly retrieved. Therefore, there exists a need for an assembly that allows a user to place personal items within one location to eliminate the need to constantly search for personal items placed in different locations.

Devices have been disclosed in the prior art that relate to electronic devices having storage compartments. These include devices that have been patented and published in patent application publications. Some of these devices provide a compartmentalized protective case with interchangeable replacement cells. Other devices provide a protective case with compartments to receive a personal electronic device and other accessories. These devices, however, fail to provide a plurality of interchangeable accessory portions and a cover having grooves along an outer edge covered to removably attach the interchangeable accessory portions.

The present invention provides an electronic device cover assembly that allows a user to store his or her personal items in the same location as his electronic device. The electronic device cover assembly includes a cover configured to receive an electronic device therein. The cover includes grooves along an outer edge of the rear portion of the cover and at least one latching fastener configured to removably attach one of a plurality of interchangeable accessory portions. The interchangeable accessory portions include a first accessory portion having a housing and at least one sliding mechanism configured to support a user's keys. The interchangeable accessory portions further include a second accessory portion having a housing divided into a plurality of compartments configured to support a user's medicinal pills. The interchangeable accessory portions also include a third accessory portion having a housing configured to support a battery configured to provide electrical power to the electronic device supported within the cover.

It is therefore submitted that the present invention is substantially divergent in design elements from the prior art, and consequently it is clear that there is a need in the art for an improvement to electronic device holding assemblies. In this regard, the instant invention substantially fulfills these needs.

### SUMMARY OF THE INVENTION

In view of the foregoing disadvantages inherent in the known types of electronic device cover assemblies now present in the prior art, the present invention provides an electronic device cover assembly, wherein the same can be utilized for providing convenience for the user when storing personal items in one location.

It is therefore an object of the invention to provide a new and improved electronic device cover assembly that has all of the advantages of the prior art and none of the disadvantages.

Another object of the present invention is to provide a new and improved electronic device cover assembly that is configured to allow a user to store additional personal items in the same location as his electronic device.

Yet another object of the present invention is to provide a new and improved electronic device cover assembly that includes a cover having a rear portion and at least one sidewall extending outwardly and perpendicularly around an outer edge configured to support an electronic device therein.

Still yet another object of the present invention is to provide a new and improved electronic device cover assembly, wherein the outer edge of the cover includes grooves having a latching fastener configured to allow one of a plurality of interchangeable accessory portions to be removably fastened thereto.

A further object of the present invention is to provide a new and improved electronic device cover assembly, wherein the plurality of interchangeable accessory portions include a first accessory portion configured to support a plurality of keys, a second accessory portion configured to support a plurality of medicinal pills, and a third accessory portion configured to support a battery.

Still yet another object of the present invention is to provide a new and improved electronic device cover assembly wherein the device may be readily fabricated from materials that permit relative economy and are commensurate with durability.

Other objects, features, and advantages of the present invention will become apparent from the following detailed description taken in conjunction with the accompanying drawings.

### BRIEF DESCRIPTIONS OF THE DRAWINGS

Although the characteristic features of this invention will be particularly pointed out in the claims, the invention itself and manner in which it may be made and used may be better understood after a review of the following description, taken in connection with the accompanying drawings wherein like numeral annotations are provided throughout.

FIG. 1 shows a side perspective of the present invention.

FIG. 2A shows a side perspective of the rear of the present invention accessory

FIG. 2B shows a cross section of an accessory portion attached to a cover of the present invention.

FIG. 3 shows a side perspective view of a first accessory portion of the present invention.

FIG. 4 shows a side perspective of a second accessory portion of the present invention.

FIG. 5 shows a side perspective of a third accessory portion of the present invention.

### DETAILED DESCRIPTION OF THE INVENTION

Reference is made herein to the attached drawings. Like reference numerals are used throughout the drawings to depict like or similar elements of the electronic device cover assembly. For the purposes of presenting a brief and clear description of the present invention, the preferred embodiment will be discussed as used for allowing a user to personal items in one location. The figures are intended for representative purposes only and should not be considered to be limiting in any respect.

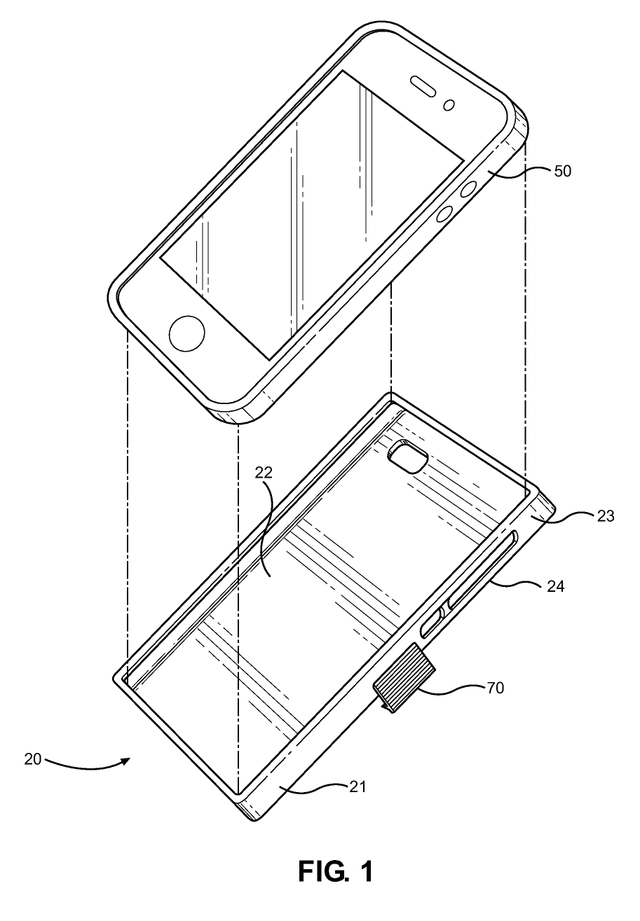

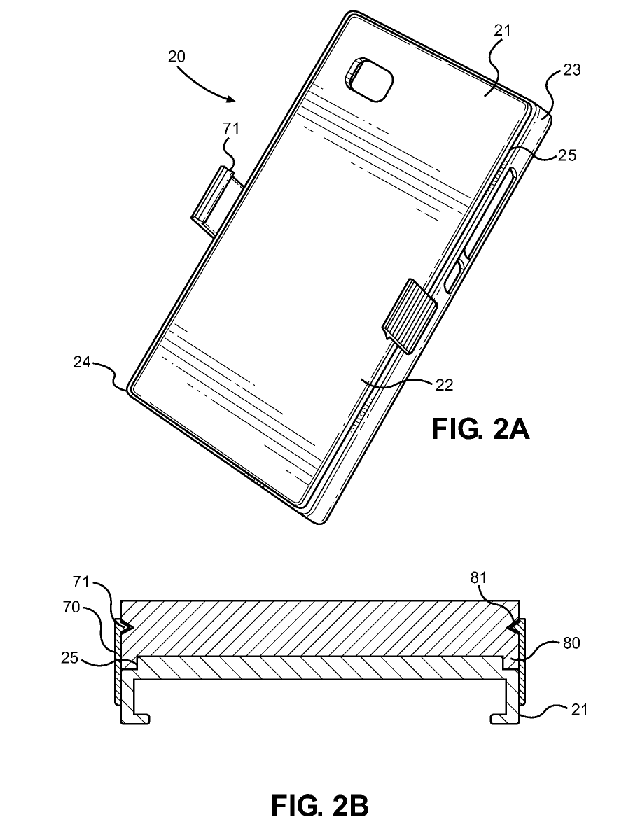

Referring now to FIGS. 1, 2A and 2B, there are shown side perspective views of the front and rear and a cross section of the electronic device cover assembly 20. The electronic device cover assembly 20 includes a cover 21 forming an interior volume configured to receive and support an electronic device 50 therein. The cover 21 includes a rear portion 22 and at least one sidewall 23 around an outer edge 24 thereof. The outer edge 24 includes grooves 25 and at least one latching fastener 70 configured to allow one of the plurality of interchangeable accessory portions to be removably fastened thereto. Preferably, the interchangeable accessory portions 26 include three accessory portions that allow a user to hold other personal items in one location with their electronic device 50.

The interchangeable accessory portions 26 are preferably rectangular in shape, however, they are sized to align and match the shape of the cover 21. Preferably, the interchangeable accessory portions 26 are smaller in size than the cover 21. In this way, a user still has access to a camera feature of his or her electronic device 50. The interchangeable accessory portions 26 include a jutting edge 80 that are configured to align with the grooves 25 of the outer edge 24. Furthermore, the latching fastener 70 includes a ridge 71 that removably fastens to a recess 81 of the interchangeable accessory portion 26 using a latching mechanism to allow for an interchangeable accessory portion 26 to be removably fastened to the cover 21.

The first accessory portion allows a user to store keys with their electronic device. The second accessory portion allows a user to store their medicinal pills with their electronic device 50. The third accessory portion includes an external battery pack that allows a user to recharge their electronic device 50 when needed. In this way, the user can store all personal items together instead of placing different items in different locations, which increases the possibility of losing these items. Other alternative embodiments may use other suitable latching fasteners configured to removably fasten one of the accessory portions thereto, and these modifications are likewise contemplated. Preferably, the cover 21 is substantially rectangular in shape and is configured to receive a rectangular electronic device 50. However, the cover 21 may also include other shapes and sizes to receive other shapes or electronic devices; these alternative shapes and sizes to cover 21 are likewise contemplated.

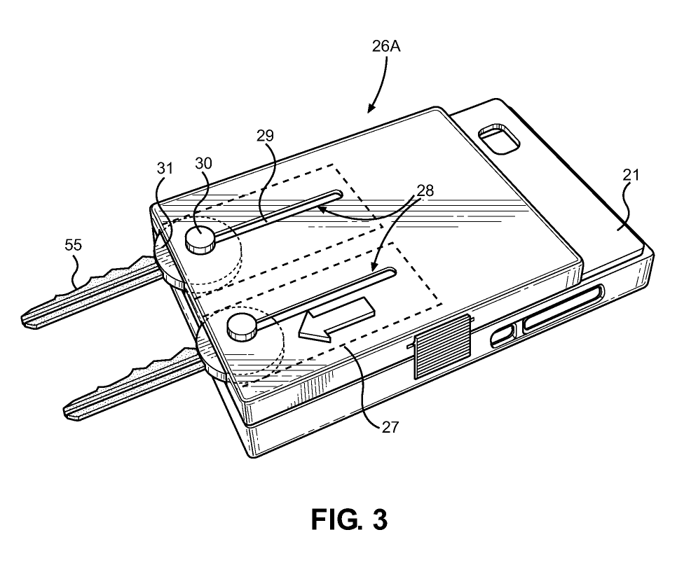

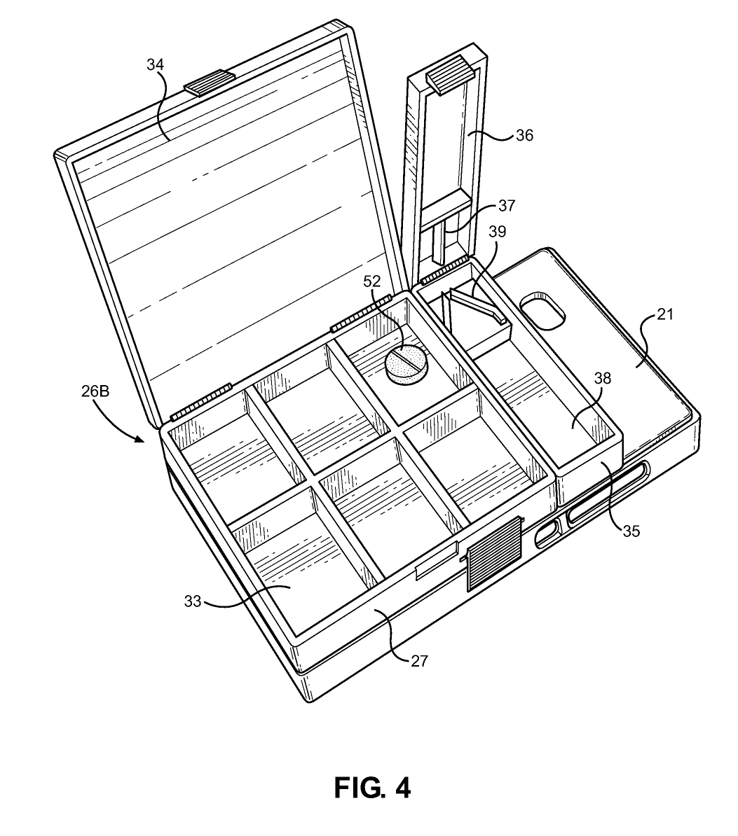

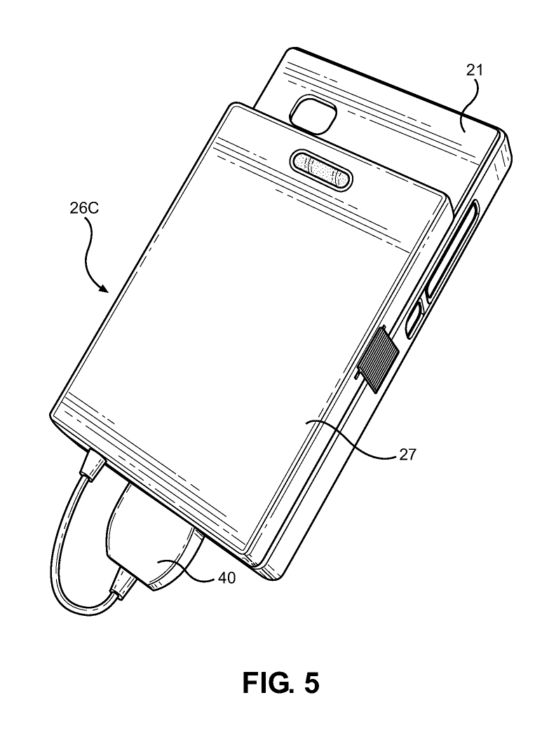

Referring now to FIGS. 3, 4, and 5, there are shown several side perspective views of the interchangeable accessory portions 26A, 26B, 26C. As aforementioned, preferably there are three interchangeable accessory portions 26A, 26B, 26C can be removably attached to the rear portion of the cover 21. The first accessory portion 26A is configured to allow a user to attach a plurality of keys 55 thereto. In this way, a user's keys 55 will always be located with his electronic device, and he will no longer fear losing his keys 55. The second accessory portion 26B is configured to receive a user's medicinal pills 52, which allows a user to conveniently place his medicinal pills with his electronic device and not in a separate container that can be easily lost. Lastly, the third accessory portion 26C includes a battery 40 that can be electrically connected to the electronic device 50 to allow for the electronic device 50 to be electrically charged. As illustrated, the accessory portions 26A, 26B, 26C are rectangular in shape, however, the size and shape of the accessory portions 26A, 26B and 26C are dependent on the shape and size of the cover 21.

The accessory portion 26A includes a housing 27 having an open end providing access to an interior volume configured to support at least one sliding mechanism 28 extending in a longitudinal direction along the housing 27 for receiving and retaining at least part of the sliding mechanism 28 within the housing 27. In this way, the sliding mechanism 28 is configured to extend and retract a key 55 into and out of the housing 27. Each sliding mechanism 28 includes a slit 29, a thumb actuator 30, and a mounting portion 31. The thumb actuator 30 is preferably integral with the mounting portion 31 and extends along the slit 29. Furthermore, the mounting portion 31 includes a mounting mechanism that is configured to removably mount the key 55 thereon. In this way, a user can use the thumb actuator 30 to extend and retract the key 55 from the housing 27 along the slit 29. The key 55 can also be protected by the housing 27 when in storage.

In the illustrated example, the accessory portion 26A includes two sliding mechanisms 28, which are positioned such that the thumb actuator 30 can be actuated longitudinally from an upper side to a lower side of the accessory portion 26A to expose the key 55. In addition, it is contemplated that in order to avoid user interference with neighboring sliding mechanisms 28, the sliding mechanisms 28 may be alternatingly positioned on opposite sides of the accessory portion 26A. Those skilled in the art may, however, recognize that the sliding mechanisms 28 may be positioned such that all the sliding mechanisms 28 are on only one side of the accessory portion 26A or may alternate positions along the upper side and lower side of the accessory portion 26A in a different pattern than illustrated.

It is not desired at this time to limit the mounting mechanism used to removably mount a key 55 to the mounting portion 31. Those of ordinary skill in the art will readily ascertain a multitude of mounting mechanisms that allow for the mounting portion 31 to provide the advantages described within this disclosure. These variations, alterations, and modifications are deemed within the scope and spirit of this present disclosure. Purely as an exemplar, an embodiment of the accessory portion 26A may include a mount portion 31 having a mounting mechanism having two opposing side retaining plates configured to removably mount a key 55 within a recess between the opposing side retaining plates. Other suitable mounting mechanisms are likewise contemplated.

The second accessory portion 26B can be interchanged with the first accessory portion 26A. The second accessory portion 26B includes a housing 27 forming an interior volume that is divided into a plurality of compartments 33. As illustrated, the interior volume is divided into six compartments 33 that are of equal area. However, other sizes, shapes, or numbers of compartments 33 are likewise contemplated. The compartments 33 are configured to receive and support at least one medicinal pill 52 therein. The housing 27 further includes a hinged closure 34 configured to provide access to the interior volume and the plurality of compartments 33. In this way, the accessory portion 26B is particularly advantageous as a user does not need to carry a separate pill container that can be lost or stolen.

In some embodiments, like the illustrated embodiment, the housing 27 also includes a pill splitting portion 35. The pill splitting portion 35 includes a positioner 39 configured to support a pill thereon to be split. In addition, the pill splitting portion 35 includes a hinged lid 36 having a blade 37 thereon configured to be hand actuated to split a pill in half. The unused half of the pill can be placed within a compartment 38 of the pill splitting portion 35. As readily ascertained by those of ordinary skill in the art, there are a variety of pill splitting portions 35 readily available in the art that may be alternatively used instead of the illustrated pill splitting portion 35. These modifications and variations are likewise contemplated.

Lastly, the accessory portion 26C can also be removably attached to the rear portion of the cover. The accessory portion 26C includes a battery pack 27 configured to be electrically connected to the electronic device to provide electrical power by a connector 40. Preferably, the battery is a rechargeable battery, however other types of suitable power sources are likewise contemplated. In addition, the connector 40 may include an 8-pin dock connector or a 30-pin dock connector, however, alternative embodiment may utilize other suitable connectors.

It is therefore submitted that the instant invention has been shown and described in what is considered to be the most practical and preferred embodiments. It is recognized, however, that departures may be made within the scope of the invention and that obvious modifications will occur to a person skilled in the art. With respect to the above description then, it is to be realized that the optimum dimensional relationships for the parts of the invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention.

Therefore, the foregoing is considered as illustrative only of the principles of the invention. Further, since numerous modifications and changes will readily occur to those skilled in the art, it is not desired to limit the invention to the exact construction and operation shown and described, and accordingly, all suitable modifications and equivalents may be resorted to, falling within the scope of the invention.

I claim:

1. An electronic device cover assembly, comprising:
a cover having a rear portion and at least one sidewall extending outwardly and perpendicularly around an outer edge thereof, wherein said cover is configured to receive and support an electronic device therein;
said cover includes grooves and at least one latching fastener configured to allow one of a plurality of interchangeable accessory portions to be removably fastened thereto;
wherein said plurality of interchangeable accessory portions each include a jutting edge configured to align with the grooves, and at least one recess;
wherein each recess is configured to receive one of said at least one latching fastener;
said plurality of interchangeable accessory portions configured to secure one or more personal items.

2. The electronic device cover assembly of claim 1, wherein:
a first accessory portion is configured to support one or more keys and includes a housing forming an interior volume having at least one sliding mechanism extending in a longitudinal direction along said housing;
wherein each of said at least one sliding mechanism is configured to extend and retract one of said one or more keys into and out of said housing.

3. The electronic device cover assembly of claim 3, wherein:
each said sliding mechanism comprises a slit, a thumb actuator and a mounting portion;
wherein said slit provides access to said interior volume,
wherein said mounting portion on which a key is disposed is located within said interior volume;
wherein said thumb actuator is secured to said mounting portion and extends through said slit so as to allow a user to manually extend and retract said key.

4. The electronic device cover assembly of claim 1, wherein a second accessory includes a housing forming an interior volume that is divided into a plurality of compartments in which one or more pills can be stored.

5. The electronic device cover assembly of claim 4, said housing includes a hinged closure configured to provide access to said interior volume and said plurality of compartments.

6. The electronic device cover assembly of claim 5, said housing further includes a pill splitting portion, wherein said pill splitting portion includes a positioner configured to support said pill thereon.

7. The electronic device cover assembly of claim 6, wherein said pill splitting portion further includes a hinged lid having a blade thereon configured to split said pill in half supported by said positioner.

8. The electronic device cover assembly of claim 6, wherein said pill splitting portion further includes a compartment for an unused split pill.

9. The electronic device cover assembly of claim 1, wherein a third accessory portion includes a battery pack that is configured to be electrically connected to said electronic device.

10. The electronic device cover assembly of claim 9, wherein said battery pack includes a connector configured to allow said battery pack to be electrically connected to said electronic device.

11. The electronic device cover assembly of claim 9, said connector includes an 8-pin connector dock.
